(19) United States
(12) Patent Application Publication
(10) Pub. No.: US 2026/0214857 A1
(43) Pub. Date: Jul. 23, 2026

(54) CONNECTOR DEVICE AND HEAT DISSIPATION STRUCTURE FOR THE SAME

(71) Applicants: JAPAN AVIATION ELECTRONICS INDUSTRY, LIMITED, Tokyo (JP); Nintendo Co., LTD., Kyoto-shi (JP)

(72) Inventors: Ryota SAITO, Tokyo (JP); Takafumi NISHIDA, Kyoto (JP); Hironori FURUIKE, Kyoto (JP); Hiroki IKUTA, Kyoto (JP)

(73) Assignees: JAPAN AVIATION ELECTRONICS INDUSTRY, LIMITED, Tokyo (JP); Nintendo Co., LTD., Kyoto-shi (JP)

(21) Appl. No.: 19/408,411

(22) Filed: Dec. 4, 2025

(30) Foreign Application Priority Data
Jan. 17, 2025 (JP) 2025-006842

(51) Int. Cl. H05K 7/20; G06K 7/00; H01R 12/70; H01R 12/71

(52) U.S. Cl. CPC H05K 7/20418; G06K 7/0056; H01R 12/707; H01R 12/714; H05K 7/20454; H05K 7/20481; H05K 7/205

(57) ABSTRACT

A heat dissipation structure is configured to reduce temperature rise of a card. The heat dissipation structure has a board, a connector device and a heat dissipation member. The board is formed with a through hole. The connector device has a card connector and a bracket made of metal. The card connector is configured to accommodate the card and is mounted on the board in an up-down direction. The card connector has a shell. The shell has an upper plate. The bracket has a terminal and a cover. The terminal is soldered in the through hole of the board. The cover of the bracket is connected to the upper plate of the shell. The heat dissipation member is connected to the cover.

### CROSS REFERENCE TO RELATED APPLICATIONS

This application is based on and claims priority under 35 U.S.C. § 119 to Japanese Patent Application No. JP 2025-006842 filed Jan. 17, 2025, the content of which is incorporated herein in its entirety by reference.

### BACKGROUND OF THE INVENTION

This invention relates to a heat dissipation structure for reducing temperature rise of a card accommodated in a card connector.

For example, a card connector configured to accommodate a memory card (hereafter, simply referred to as a card) is disclosed in JP2017-120719A (Patent Document 1), the content of which is incorporated herein by reference.

Referring to FIG. 15, Patent Document 1 discloses a card connector 90 comprising a housing 92 and a shield cover (shell) 94. The shell 94 is attached to the housing 92 so that the card connector 90 is formed with an accommodation portion 96. The accommodation portion 96 is configured to accommodate a card 98 inserted therein.

As data-transfer rate of a card is increased, the card generates more intense heat, and thereby the temperature of the card is increased. Excessive increase of the temperature of the card causes various problems.

### SUMMARY OF THE INVENTION

It is therefore an object of the present invention to provide a new heat dissipation structure for reducing temperature rise of a card accommodated in a card connector and to provide a connector device suitable for this heat dissipation structure.

An aspect of the present invention provides a heat dissipation structure configured to reduce temperature rise of a card. The heat dissipation structure comprises a board, a connector device and a heat dissipation member. The board is formed with a through hole. The connector device comprises a card connector and a bracket made of metal. The card connector is configured to accommodate the card and is mounted on the board in an up-down direction. The card connector comprises a shell. The shell has an upper plate. The bracket has a terminal and a cover. The terminal is soldered in the through hole of the board. The cover of the bracket is connected to the upper plate of the shell. The heat dissipation member is connected to the cover.

Another aspect of the present invention provides a connector device configured to reduce temperature rise of a card. The connector device comprises a card connector and a bracket made of metal. The card connector is configured to be mounted on a board in an up-down direction and is configured to accommodate the card. The card connector comprises a shell. The shell has an upper plate. The bracket has a terminal and a cover. The terminal is configured to be soldered in a through hole formed in the board. The cover of the bracket is connected to the upper plate of the shell.

According to the heat dissipation structure of an aspect of the present invention, heat generated in the card is transferred to the heat dissipation member through the upper plate of the shell and the cover of the bracket. According to this first thermal conduction path, the upper plate and the cover can be in contact with each other over a wide area, and the cover and the heat dissipation member can be in contact with each other over a wide area. Accordingly, heat-conduction performance can be improved. In addition, the metal bracket increases heat capacity of the connector device and thereby reduces temperature rise of the whole connector device including the card. Moreover, the heat generated in the card is transferred to the board through the terminal of the bracket soldered in the through hole in addition to the first thermal conduction path. This second thermal conduction path having low thermal resistance can be reliably formed by connecting the terminal of the bracket to the board not via surface mounting but via through hole, and thereby heat-conduction performance can be further improved. As described above, an aspect of the present invention provides a new heat dissipation structure for reducing temperature rise of a card accommodated in a card connector.

The connector device of an aspect of the present invention comprises the shell and the bracket each of which is a part of the heat dissipation structure of an aspect of the present invention. According to an aspect of the present invention, the heat dissipation structure can be formed merely by connecting the connector device to the heat dissipation member and soldering the terminal of the connector device in the through hole of the board. Thus, an aspect of the present invention provides a connector device suitable for the heat dissipation structure which is configured to reduce temperature rise of a card accommodated in a card connector.

An appreciation of the objectives of the present invention and a more complete understanding of its configuration may be had by studying the following description of the preferred embodiment and by referring to the accompanying drawings.

### BRIEF DESCRIPTION OF THE DRAWINGS

FIG. 1 is a perspective view showing a heat dissipation structure according to an embodiment of the present invention.

FIG. 2 is an exploded, perspective view showing the heat dissipation structure of FIG. 1, wherein an outline of a thermal conduction sheet attached to a shell and an outline of another thermal conduction sheet attached to a bracket are illustrated with dashed line.

FIG. 3 is an exploded, perspective view showing a connector device of the heat dissipation structure of FIG. 2, wherein outlines of signal terminals of the connector device and an outline of a board are partially illustrated with dashed line.

FIG. 4 is a front view showing the heat dissipation structure of FIG. 1, wherein hidden outlines of the terminals of the bracket and outlines of hidden through holes of the board are illustrated with dashed line.

FIG. 5 is a partial, cross-sectional view showing the heat dissipation structure of FIG. 4, taken along line V-V, wherein an upper part of a heat sink is not illustrated, and a hidden outline of a connection portion of the bracket and an outline of a hidden through hole of the board are illustrated with dashed line.

FIG. 6 is a front view schematically showing the heat dissipation structure of FIG. 4, wherein thermal conduction paths are illustrated with dashed line.

FIG. 7 is a cross-sectional view schematically showing the heat dissipation structure of FIG. 6, taken along line VII-VII, wherein thermal conduction paths are illustrated with dashed line.

FIG. 8 is a top view showing the connector device of FIG. 3, wherein positions of hidden passing holes and hidden peripheral holes of a card connector and positions of surface mount portions of hidden signal terminals are illustrated with dashed line.

FIG. 9 is a top view showing the card connector of the connector device of FIG. 8, wherein positions of hidden signal terminals and positions of windows formed in a shell of a card connector of a second modification are partially illustrated with dashed line.

FIG. 10 is a top view showing a first modification of the connector device of FIG. 8, wherein positions of hidden passing holes and hidden peripheral holes of a card connector are illustrated with dashed line.

FIG. 11 is a perspective view showing a bracket of the connector device of FIG. 10.

FIG. 12 is a top view showing the second modification of the connector device of FIG. 8, wherein positions of surface mount portions of hidden signal terminals are illustrated with dashed line.

FIG. 13 is a top view showing a card connector of the connector device of FIG. 12.

FIG. 14 is a perspective view showing a third modification of the connector device of FIG. 8, wherein a part of an outline of the board and positions of surface mount portions of hidden signal terminals are illustrated with dashed line.

FIG. 15 is a perspective view showing a card connector of Patent Document 1.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION

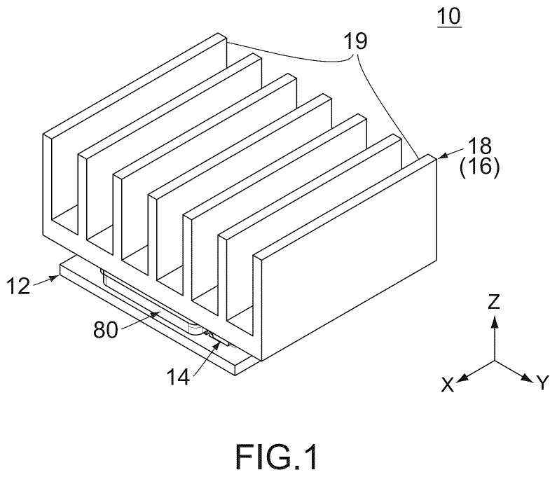

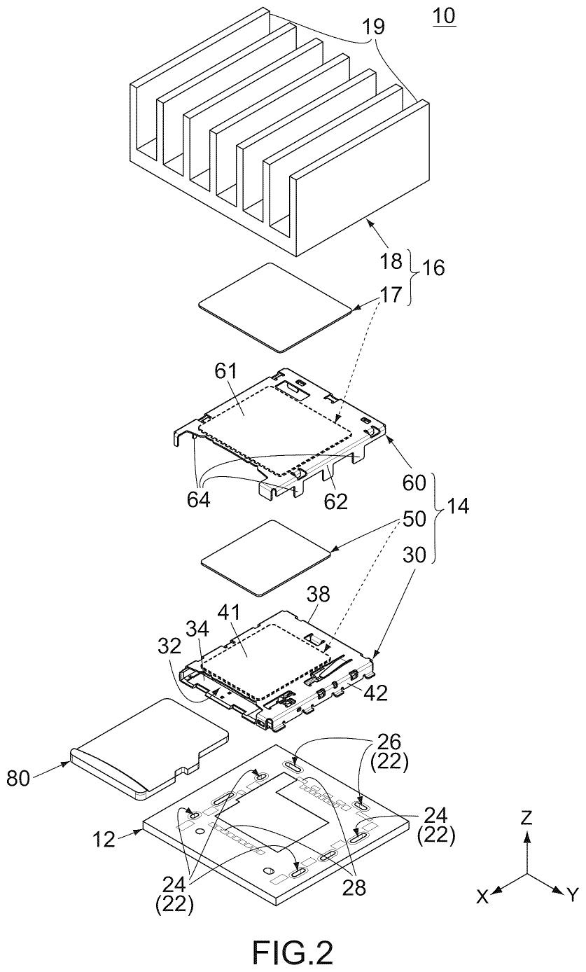

As shown in FIGS. 1 and 2, a heat dissipation structure 10 according to an embodiment of the present invention comprises a board 12, a connector device 14 and a heat dissipation member 16. The board 12, the connector device 14 and the heat dissipation member 16 are stacked on each other and are fixed to each other in an up-down direction and are combined into the heat dissipation structure 10.

The up-down direction of the present embodiment is the Z-direction. In the present embodiment, “upward” means the positive Z-direction, and “downward” means the negative Z-direction. The words such as the up-down direction do not indicate the absolute positional relation relative to the ground but merely indicate a relative positional relation under a definition that the board 12, the connector device 14 and the heat dissipation member 16 are vertically arranged.

Referring to FIG. 2, the board 12 of the present embodiment is a circuit board which is formed with various conductive patterns. The illustrated board 12 is a part of an actual circuit board connected to a control circuit (not shown) and has a rectangular flat-plate shape perpendicular to the up-down direction. The board 12 is formed with a large number of through holes 22 and is provided with a large number of conductive pads 28 each made of conductor. Each of the through holes 22 passes through the board 12 in the up-down direction and is grounded to a ground pattern (not shown) of the board 12. Each of the conductive pads 28 is formed on an upper surface of the board 12. At least one of the conductive pads 28 is electrically connected with the control circuit through a conductive line (not shown) made of conductor. At least a remaining one of the conductive pads 28 is grounded to the ground pattern of the board 12.

The through holes 22 of the present embodiment include six side through holes (through holes) 24 and two rear through holes (through holes) 26. The six through holes 24 are divided into two rows in a lateral direction perpendicular to the up-down direction. Each row of the through holes 24 consists of three of the through holes 24. The lateral direction of the present embodiment is the Y-direction. The three through holes 24 of each row are arranged along a front-rear direction perpendicular to both the up-down direction and the lateral direction. The two through holes 26 are located at a rear end part of the board 12 and are arranged in the lateral direction. The front-rear direction of the present embodiment is the X-direction. In the present embodiment, “forward” means the positive X-direction, and “rearward” means the negative X-direction.

The board 12 of the present embodiment has the aforementioned configuration. However, the present invention is not limited thereto. The configuration of the board 12 is not specifically limited, provided that the board 12 is formed with one or more of the through holes 24.

The connector device 14 of the present embodiment comprises a card connector 30, a bracket 60 made of metal and a thermal conduction sheet 50 made of thermal conductive material and having flexibility. The card connector 30 is configured to be mounted on the board 12 in the up-down direction and is configured to accommodate a card 80. The thus-configured card connector 30 is mounted on the board 12 in the up-down direction and accommodates the card 80 when the connector device 14 is used. The card 80 is a memory card such as a micro-SD card and memorizes various data. The data memorized in the card 80 is transferred between the card connector 30 and the control circuit (not shown) via the board 12.

In general, data-transfer rate of a memory card is gradually increased in accordance with technology progress. As data-transfer rate of the card 80 is increased, the card 80 generates more intense heat, and thereby the temperature of the card 80 is increased. Excessive increase of the temperature of the card 80 causes various problems.

As described below, the heat dissipation structure 10 of the present embodiment has a new configuration for reducing temperature rise of the card 80 accommodated in the card connector 30. In other words, the heat dissipation structure 10 of the present embodiment is configured to reduce temperature rise of the card 80. The connector device 14 of the present embodiment is also configured to reduce temperature rise of the card 80. For example, the connector device 14 of the present embodiment is connected to the heat dissipation member 16. The heat generated in the connector device 14, or the heat generated in the card connector 30, is effectively transferred to the heat dissipation member 16. The heat transferred to the heat dissipation member 16 is dissipated out of the heat dissipation member 16.

Referring to FIG. 2 together with FIG. 5, the heat dissipation member 16 of the present embodiment comprises a heat sink 18 made of metal and a thermal conduction sheet 17 made of thermal conductive material and having flexibility. The thermal conduction sheet 17 of the present embodiment is a thin rectangular sheet. The thermal conduction sheet 17 is located between an upper surface of the connector device 14 and a lower surface of the heat sink 18 and is in close contact with the upper surface of the connector device 14 and the lower surface of the heat sink 18. According to the present embodiment, since the flexible thermal conduction sheet 17 is provided, the connector device 14 and the heat sink 18 can be in close contact with each other via the thermal conduction sheet 17 over a wide area even in an instance in which each of the upper surface of the connector device 14 and the lower surface of the heat sink 18 is formed with depressions and projections.

The heat generated in the connector device 14, or the heat generated in the card 80, is transferred to the heat sink 18 through the thermal conduction sheet 17. The heat sink 18 of the present embodiment has a large volume and thereby has a large heat capacity. In addition, the heat sink 18 has a large number of heat dissipation plates 19. The heat dissipation plates 19 are arranged in the lateral direction while being apart from each other in the lateral direction. Each of the heat dissipation plates 19 has a rectangular flat-plate shape in a vertical plane (XZ-plane) perpendicular to the lateral direction, and thereby the heat sink 18 has a wide area for dissipating heat.

The heat dissipation member 16 of the present embodiment has the aforementioned configuration. The thus-configured heat dissipation member 16 can effectively receive heat from the connector device 14 and can effectively dissipate the heat transferred from the connector device 14 into the air. However, the present invention is not limited thereto. For example, the thermal conduction sheet 17 may be provided as necessary. Thus, the heat dissipation member 16 may comprise only the heat sink 18. The heat sink 18 may be directly connected to the upper surface of the connector device 14 in an instance in which the thermal conduction sheet 17 is not provided. In this instance, the heat sink 18 may be adhered to the connector device 14 with paste-like thermal conductive material instead of the thermal conduction sheet 17. The heat dissipation member 16 may further comprise another member in addition to the aforementioned members.

According to the present embodiment, the heat generated in the card 80 is dissipated out of the heat sink 18 into the air. However, the present invention is not limited thereto. For example, the heat sink 18 may be in contact with a cooling device (not shown). The heat dissipation member 16 may comprise various members such as a metal case, a metal shield plate, a heat pipe, a vapor chamber and a copper foil sheet instead of the heat sink 18 or in addition to the heat sink 18.

Hereafter, explanation will be made about the connector device 14 of the present embodiment.

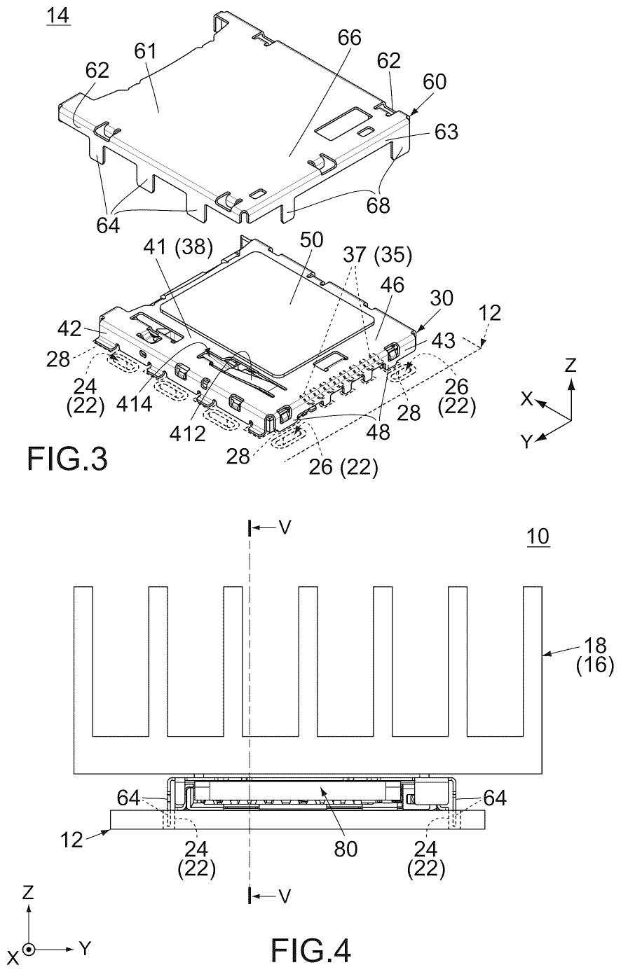

Referring to FIG. 3, the connector device 14 of the present embodiment comprises only the card connector 30, the thermal conduction sheet 50 and the bracket 60. However, the present invention is not limited thereto. For example, the connector device 14 may further comprise another member in addition to the aforementioned members.

The thermal conduction sheet 50 of the present embodiment is a thin rectangular sheet. Referring to FIG. 3 together with FIG. 5, the thermal conduction sheet 50 is located between an upper surface of the card connector 30 and a lower surface of the bracket 60 and is in close contact with the upper surface of the card connector 30 and the lower surface of the bracket 60. According to the present embodiment, since the flexible thermal conduction sheet 50 is provided, the card connector 30 and the bracket 60 can be in close contact with each other via the thermal conduction sheet 50 over a wide area even in an instance in which each of the upper surface of the card connector 30 and the lower surface of the bracket 60 is formed with depressions and projections.

The heat generated in the card connector 30, or the heat generated in the card 80, is effectively transferred to the bracket 60 through the thermal conduction sheet 50. However, the present invention is not limited thereto. For example, the thermal conduction sheet 50 may be provided as necessary. Thus, the connector device 14 may comprise only the card connector 30 and the bracket 60. The bracket 60 may be directly connected to the upper surface of the card connector 30 in an instance in which the thermal conduction sheet 50 is not provided. In this instance, the bracket 60 may be adhered to the upper surface of the card connector 30 with paste-like thermal conductive material.

Referring to FIG. 5 together with FIGS. 2 and 3, the card connector 30 of the present embodiment comprises a housing 34 made of insulator, a plurality of signal terminals 35 each made of metal and a shell 38 made of metal. The housing 34 is located at a lower part of the card connector 30. The shell 38 covers the housing 34 from above so that the card connector 30 is formed with an accommodation portion 32. The accommodation portion 32 is a space which is located between the housing 34 and the shell 38 in the up-down direction. The accommodation portion 32 opens forward. The card 80 is inserted into the accommodation portion 32 from the front and is accommodated in the accommodation portion 32 when the connector device 14 is used. The card 80 accommodated in the accommodation portion 32 is covered by the shell 38 from above.

Referring to FIG. 5 together with FIG. 3, the signal terminals 35 are held by the housing 34 and are arranged in the lateral direction. Each of the signal terminals 35 has a contact point 36 and a surface mount portion 37. The surface mount portions 37 are located at a rear end part of the card connector 30 and are arranged in the lateral direction. Referring to FIG. 5, each of the surface mount portions 37 is fixed on and is connected to the conductive pad 28 of the board 12 via soldering when the connector device 14 is mounted on the board 12. The connector device 14, or the card connector 30, which is mounted on the board 12 as described above, is fixed and connected to the board 12. Each of the contact points 36 is pressed against and is brought into contact with an electrode (not shown) of the card 80 when the card 80 is accommodated in the accommodation portion 32. As a result, the card 80 and the control circuit (not shown) are electrically connected with each other.

The card connector 30 of the present embodiment has the aforementioned configuration. All of lower end parts of the card connector 30 which are configured to be connected to the board 12 are configured to be surface mounted on the board 12 including unillustrated lower end parts of the card connector 30. Accordingly, the card connector 30 can be fixed to the board 12 even if the board 12 is formed with none of the through holes 22 each of which occupies a wide area in comparison with the conductive pad 28. However, the configuration of the card connector 30 of the present invention is not specifically limited, provided that the card connector 30 comprises the shell 38 which is configured to cover the accommodated card 80. For example, the card connector 30 may further comprise another member in addition to the aforementioned members. The card connector 30 may be partially inserted into and connected to the through holes 22.

Referring to FIG. 3, the shell 38 of the present embodiment is formed by bending a single metal plate. Thus, the shell 38 is a single metal plate with bends. The shell 38 has an upper plate 41, two side plates 42, a rear plate 43 and five connection portions 48. Each of the upper plate 41, the side plates 42, the rear plate 43 and the connection portions 48 is a part of a single metal plate.

The upper plate 41 is located at an upper end of the shell 38 and has a rectangular flat-plate shape perpendicular to the up-down direction as a whole. The thus-shaped upper plate 41 has an upper surface which extends along a horizontal plane (XY-plane) perpendicular to the up-down direction. The upper surface of the upper plate 41 has a middle part in the horizontal plane which is a flat surface with no depressions, no projections and no holes. The shell 38 has opposite side parts which are located at opposite sides of the upper plate 41 in the lateral direction, respectively. These opposite side parts are bent downward, and thereby the shell 38 is formed with the two side plates 42. Each of the side plates 42 extends along the vertical plane (XZ-plane) as a whole. Each of the side plates 42 has some parts each of which further extends downward and is fixed on and is connected to the conductive pad 28 of the board 12 via soldering. The shell 38 has a rear part which is located at a rear end of the upper plate 41. This rear part is bent downward, and thereby the shell 38 is formed with the rear plate 43. The rear plate 43 extends along a perpendicular plane (YZ-plane) perpendicular to the front-rear direction as a whole.

The shell 38 of the present embodiment has a shield 46 in addition to the aforementioned portions. The shield 46 of the present embodiment is a portion which consists of a rear end part of the upper plate 41 and the rear plate 43. There is no visible boundary provided between the shield 46 and a front part of the upper plate 41. The connection portions 48 are provided on the rear plate 43 of the shield 46 and are arranged along the lateral direction. Each of the connection portions 48 extends downward from the shield 46. In detail, each of the connection portions 48 extends straight downward from a lower end of the rear plate 43 of the shield 46.

Each of the connection portions 48 is configured to be connected to the board 12. More specifically, during a process in which the connector device 14 is fixed to the board 12, the lower end of each of the connection portions 48 is brought into contact with the conductive pad 28 of the board 12 or is located just over the conductive pad 28 with a slight distance formed therebetween. Each of the thus-arranged connection portions 48 is then fixed on the conductive pad 28 via soldering to be grounded. However, the present invention is not limited thereto. Each of the connection portions 48 may be configured to be soldered in the through hole 22 formed in the board 12.

The shell 38 of the present embodiment has the aforementioned configuration. However, the present invention is not limited thereto. For example, the shield 46 and the connection portions 48 may be provided as necessary. The number of the connection portions 48 may be one or more. The shell 38 may be provided with a visible boundary located between the shield 46 and the front part of the upper plate 41. The shell 38 may further comprise another portion in addition to the aforementioned portions. The shell 38 may be formed of a plurality of members joined together.

Referring to FIG. 3 together with FIG. 2, the bracket 60 of the present embodiment is formed by bending a single metal plate. Thus, the bracket 60 is a single metal plate with bends. The bracket 60 has a cover 61, two side plates 62, a rear plate 63, six terminals 64 and two connection portions 68. Each of the cover 61, the side plates 62, the rear plate 63, the terminals 64 and the connection portions 68 is a part of a single metal plate.

The cover 61 is located at an upper end of the bracket 60 and has a rectangular flat-plate shape which extends along the horizontal plane as a whole. The thus-shaped cover 61 has an upper surface and a lower surface each of which extends along a horizontal plane (XY-plane). Each of the upper surface and the lower surface has a middle part in the horizontal plane which is a flat surface with no depressions, no projections and no holes. The bracket 60 has opposite side parts which are located at opposite sides of the cover 61 in the lateral direction, respectively. These opposite side parts are bent downward, and thereby the bracket 60 is formed with the two side plates 62. Each of the side plates 62 extends along the vertical plane (XZ-plane) as a whole. The bracket 60 has a rear part which is located at a rear end of the cover 61. This rear part is bent downward, and thereby the bracket 60 is formed with the rear plate 63. The rear plate 63 extends along the perpendicular plane (YZ-plane) as a whole.

The bracket 60 of the present embodiment has a shield 66 in addition to the aforementioned portions. The shield 66 of the present embodiment is a portion which consists of a rear end part of the cover 61 and the rear plate 63. There is no visible boundary provided between the shield 66 and a front part of the cover 61. The connection portions 68 are provided on the rear plate 63 of the shield 66 and are arranged along the lateral direction. Each of the connection portions 68 extends downward from the shield 66. In detail, each of the connection portions 68 extends straight downward from a lower end of the rear plate 63 of the shield 66.

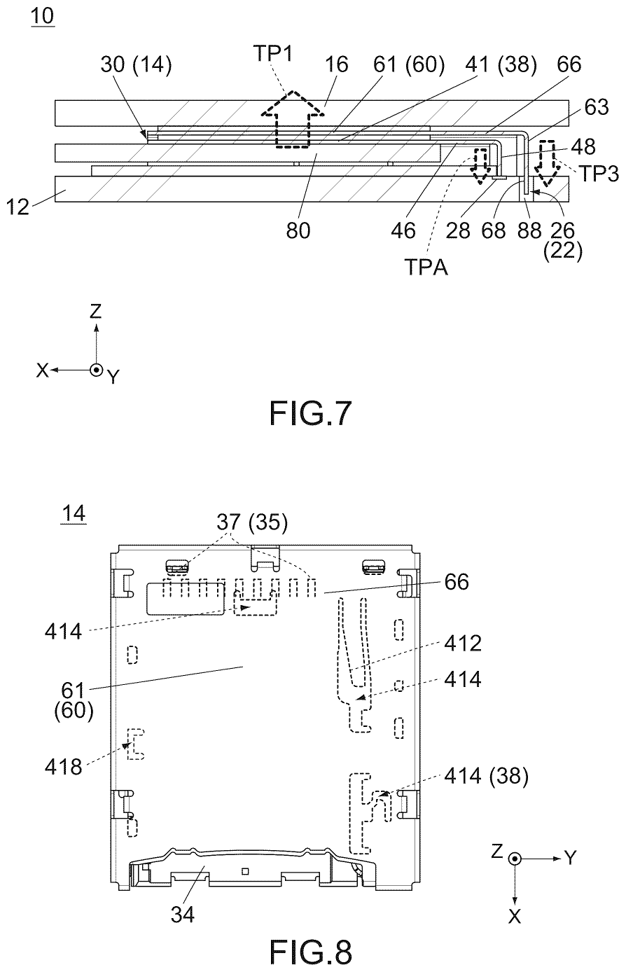

Each of the connection portions 68 is configured to be soldered in the through hole 26 formed in the board 12. More specifically, referring to FIGS. 5 and 7, a lower end of each of the connection portions 68 is inserted into the through hole 26 of the board 12 during a process in which the connector device 14 is fixed to the board 12. The thus-inserted lower end of each of the connection portions 68 is then fixed in the through hole 26 by the solder 88 filled in the through hole 26. As described above, each of the connection portions 68 is soldered in the through hole 26 of the board 12 when the connector device 14 is used.

Referring to FIGS. 2, 3 and 6, each of the side plates 62 extends downward from an end of the cover 61 in the lateral direction. Referring to FIGS. 2 and 3, the six terminals 64 are divided into two rows in the lateral direction. Each row of the terminals 64 consists of three of the terminals 64. The two rows of the terminals 64 are provided so as to correspond to the two side plates 62, respectively. The three terminals 64 of each row are arranged along the front-rear direction and extend downward from the corresponding side plate 62. In detail, each of the terminals 64 of each row extends straight downward from a lower end of the side plate 62.

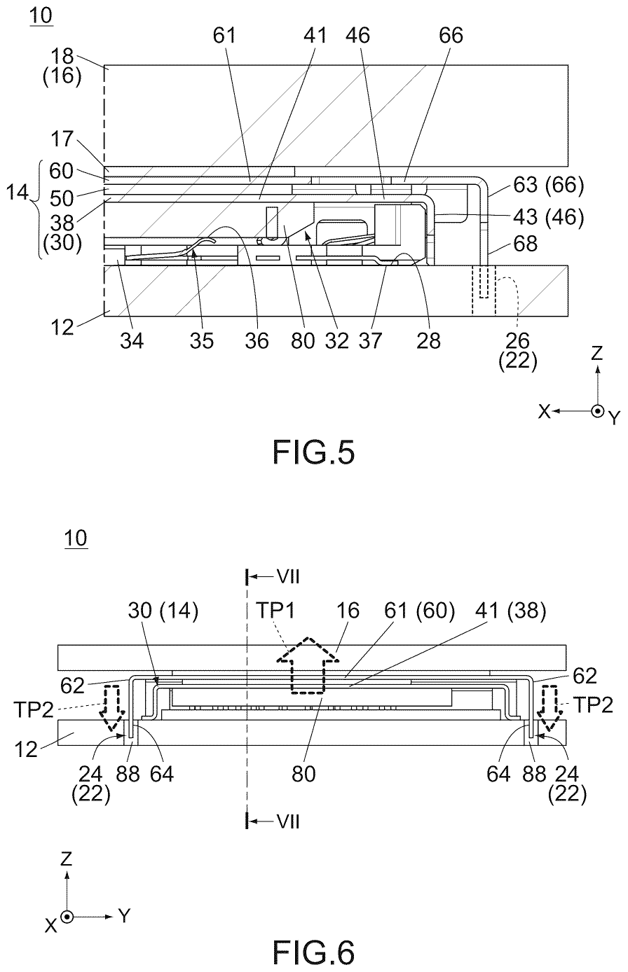

Referring to FIGS. 3, 4 and 6, each of the terminals 64 is configured to be soldered in the through hole 24 formed in the board 12. More specifically, referring to FIGS. 4 and 6, a lower end of each of the terminals 64 is inserted into the through hole 24 of the board 12 during a process in which the connector device 14 is fixed to the board 12. The thus-inserted lower end of each of the terminals 64 is fixed in the through hole 24 by the solder 88 filled in the through hole 24.

Referring to FIG. 3, the thermal conduction sheet 50 is connected to the upper plate 41 of the shell 38. In detail, the thermal conduction sheet 50 is adhered on the upper surface of the front part of the upper plate 41. The thermal conduction sheet 50 is not connected to the shield 46. In other words, the shield 46 of the upper plate 41 is the rear end part of the upper plate 41 which is not adhered to the thermal conduction sheet 50. Referring to FIG. 3 together with FIG. 5, the thermal conduction sheet 50 is connected to the cover 61 of the bracket 60. In detail, the thermal conduction sheet 50 is adhered to the lower surface of the cover 61.

As described above, the cover 61 of the bracket 60 of the present embodiment is indirectly connected to the upper plate 41 of the shell 38 via the thermal conduction sheet 50. According to the present embodiment, since the flexible thermal conduction sheet 50 is provided, the upper plate 41 and the cover 61 can be in close contact with each other via the thermal conduction sheet 50 over a wide area even in an instance in which each of the upper surface of the upper plate 41 and the lower surface of the cover 61 is provided with depressions and projections. However, the present invention is not limited thereto. For example, the cover 61 may be directly connected to the upper plate 41 with none of the thermal conduction sheet 50 located therebetween. In any instance, the cover 61 of the bracket 60 is connected to the upper plate 41 of the shell 38.

According to the present embodiment, the bracket 60 has lower end parts (connection ends) which are configured to be connected to the board 12. All of the connection ends are not configured to be surface mounted on the board 12 but are configured to be soldered in the through holes 22 of the board 12. Considering manufacturing tolerance and assembly tolerance, it is difficult to accurately position the bracket 60 relative to the board 12 in the up-down direction since the bracket 60 is attached to the shell 38 from above. Thus, it is difficult to surface mount the connection ends of the bracket 60 of the present embodiment on the board 12. In contrast, according to the present embodiment, the connection ends can be easily inserted into and soldered in the through holes 22 of the board 12 merely by making the connection ends of the bracket 60 long. Moreover, the connector device 14 can be securely fixed to the board 12 by soldering the connection ends of the bracket 60 in the through holes 22.

The bracket 60 of the present embodiment has the aforementioned configuration. However, the present invention is not limited thereto. For example, the shield 66 and the connection portions 68 may be provided as necessary. Each of the connection portions 68 may be surface mounted on the board 12. The number of the connection portions 68 may be one or more. The bracket 60 may be provided with a visible boundary located between the shield 66 and the front part of the cover 61. The bracket 60 may further comprise another portion in addition to the aforementioned portions. The bracket 60 may be formed of a plurality of members joined together.

Hereafter, explanation will be made about main thermal conduction paths of the present embodiment.

Referring to FIGS. 6 and 7, the heat dissipation member 16 is connected to the cover 61 of the bracket 60 when the connector device 14 is used. Referring to FIG. 6, each of the terminals 64 of the bracket 60 is soldered in the through hole 24 of the board 12 when the connector device 14 is used.

Referring to FIGS. 6 and 7, according to the heat dissipation structure 10 of the present embodiment, almost all the heat generated in the card 80 is transferred to the upper plate 41 of the shell 38. The heat transferred to the upper plate 41 is transferred to the heat dissipation member 16 through the cover 61 of the bracket 60. According to this first thermal conduction path, the upper plate 41 and the cover 61 can be in contact with each other over a wide area, and the cover 61 and the heat dissipation member 16 can be in contact with each other over a wide area. Accordingly, heat-conduction performance can be improved. In addition, the metal bracket 60 increases heat capacity of the connector device 14 and thereby reduces temperature rise of the whole connector device 14 including the card 80.

Moreover, the heat generated in the card 80 is transferred to the board 12 through the terminals 64 of the bracket 60 soldered in the through holes 24 in addition to the first thermal conduction path TP1. According to the present embodiment, each of the terminals 64 of the bracket 60 is connected to the board 12 not via surface mounting but via the solder 88 which fills the through hole 24. Accordingly, the terminals 64 can be securely connected to the board 12, and the thermal resistance between the terminals 64 and the board 12 can be reduced. Thus, according to the present embodiment, a second thermal conduction path TP2 which has small thermal resistance can be reliably formed, and thereby heat-conduction performance can be further improved.

As described above, the present embodiment provides the new heat dissipation structure 10 for reducing temperature rise of the card 80 accommodated in the card connector 30.

The connector device 14 of the present embodiment comprises the shell 38 and the bracket 60 each of which is a member of the heat dissipation structure 10 of the present embodiment. According to the present embodiment, the heat dissipation structure 10 can be formed merely by connecting the connector device 14 to the heat dissipation member 16 and soldering the terminals 64 of the connector device 14 in the through holes 24 of the board 12. Thus, the present embodiment provides the connector device 14 suitable for the new heat dissipation structure 10 which is configured to reduce temperature rise of the card 80 accommodated in the card connector 30.

Referring to FIG. 7, according to the present embodiment, the heat generated in the card 80 is transferred to the board 12 through the connection portions 68 of the bracket 60 which are soldered in the through holes 26 in addition to the first thermal conduction path TP1 and the second thermal conduction path TP2. Each of the connection portions 68 of the bracket 60 is connected to the board 12 not via surface mounting but via the solder 88 which fills the through hole 26. Accordingly, the connection portions 68 can be securely connected to the board 12, and the thermal resistance between the connection portions 68 and the board 12 can be reduced. Thus, according to the present embodiment, a third thermal conduction path TP3 which has small thermal resistance can be reliably formed, and thereby heat-conduction performance can be further improved.

Referring to FIG. 3, according to the present embodiment, heat-conduction performance can be easily improved by making each of the terminals 64 and the connection portions 68 of the bracket 60 wide. Moreover, heat-conduction performance can be easily improved by increasing the number of the terminals 64 and the number of the connection portions 68.

Hereafter, further specific explanation will be made about the connector device 14 of the present embodiment.

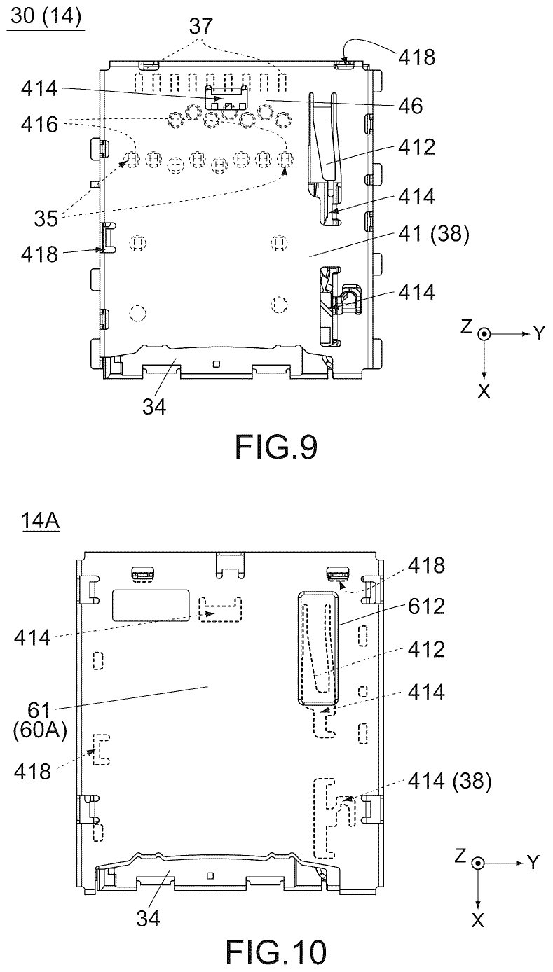

Referring to FIG. 9 together with FIG. 3, the upper plate 41 of the shell 38 is sometimes formed with a large number of windows 416 for the purpose such as visual inspection of the signal terminals 35. Each of the windows 416 is formed so as to pass through the upper plate 41 in the up-down direction. The thus-formed windows 416 degrade electromagnetic shielding function of the shell 38. In addition, the thus-formed windows 416 reduce an adhered area between the upper plate 41 and the thermal conduction sheet 50. As a result, heat-conduction performance might be degraded.

In contrast, the upper plate 41 of the shell 38 of the present embodiment is formed with none of the windows 416. This configuration prevents the shell 38 from being degraded in electromagnetic shielding function to some extent. In addition, since most of the upper plate 41 is formed with no hole, an adhered area between the upper plate 41 and the thermal conduction sheet 50 can be made large by adhering the thermal conduction sheet 50 having a wide area on the upper plate 41.

Referring to FIG. 9, the upper plate 41 of the shell 38 of the present embodiment is not formed with the windows 416 but is formed with three passing holes 414 and eight peripheral holes 418. Each of the peripheral holes 418 is located at a periphery (edge) of the upper plate 41 in the horizontal plane and only partially passes through the upper plate 41 in the up-down direction. Each of the peripheral holes 418 has a small size. The peripheral holes 418 which are formed as described above do not substantially affect the electromagnetic shielding function of the shell 38. Accordingly, the peripheral holes 418 do not need to be covered unless there is a particular reason to do so. In contrast to the peripheral holes 418, each of the passing holes 414 is located at a part of the upper plate 41 other than a periphery (edge) of the upper plate 41 in the horizontal plane. In other words, each of the passing holes 414 is located at a middle part of the upper plate 41 in the horizontal plane. Each of the passing holes 414 passes through the upper plate 41 in the up-down direction. Each of the passing holes 414 has a large size.

Each of the passing holes 414 of the shell 38 is a necessary hole for the function of the card connector 30 and is hard to cover. For example, one of the passing holes 414 is provided with a spring piece 412 which is resiliently deformable. The spring piece 412 is a portion which is necessary for properly accommodating and ejecting the card 80 (see FIG. 1). The spring piece 412 has an end which is configured to be moved upward beyond the upper surface of the upper plate 41 in accordance with resilient deformation of the spring piece 412. If this passing hole 414 is covered, the end of the spring piece 412 cannot be moved upward and the card 80 cannot be properly accommodated and ejected.

Referring to FIG. 3, the thermal conduction sheet 50 of the present embodiment is adhered to the middle part of the upper plate 41 of the shell 38 which is formed with none of the passing holes 414. Referring to FIG. 3 together with FIGS. 5 and 8, according to the aforementioned arrangement, the lower surface of the bracket 60 which is attached to the shell 38 via the thermal conduction sheet 50 is located above the spring piece 412 while being apart from the upper plate 41 of the shell 38 by a distance which is equal to a thickness of the thermal conduction sheet 50. Accordingly, the end of the spring piece 412 is movable in a necessary movement distance. Thus, according to the present embodiment, the bracket 60 can cover all the passing holes 414 from above with no affection to the function of the spring piece 412.

Referring to FIG. 8, as described above, the cover 61 of the bracket 60 of the present embodiment covers the passing holes 414. The passing holes 414 are invisible when the connector device 14 is seen from above. Referring to FIG. 2, according to this arrangement, the thermal conduction sheet 17 can be adhered to the cover 61 over a wide area. Moreover, the cover 61 of the present embodiment has almost no holes. Accordingly, an adhered area between the bracket 60 and the thermal conduction sheet 17 can be made large. Thus, according to the present embodiment, a thermal conduction area between the connector device 14 and the heat dissipation member 16 can be made large by attaching the bracket 60 to the shell 38. However, the present invention is not limited thereto. The configuration of the connector device 14 can be modified as necessary.

For example, comparing FIG. 10 with FIG. 8, a connector device 14A according to a first modification comprises a bracket 60A different from the bracket 60 of the connector device 14. The bracket 60A is provided with a protruding portion 612 which is not provided on the bracket 60. The protruding portion 612 is formed so as to cover the spring piece 412 of the shell 38 from above.

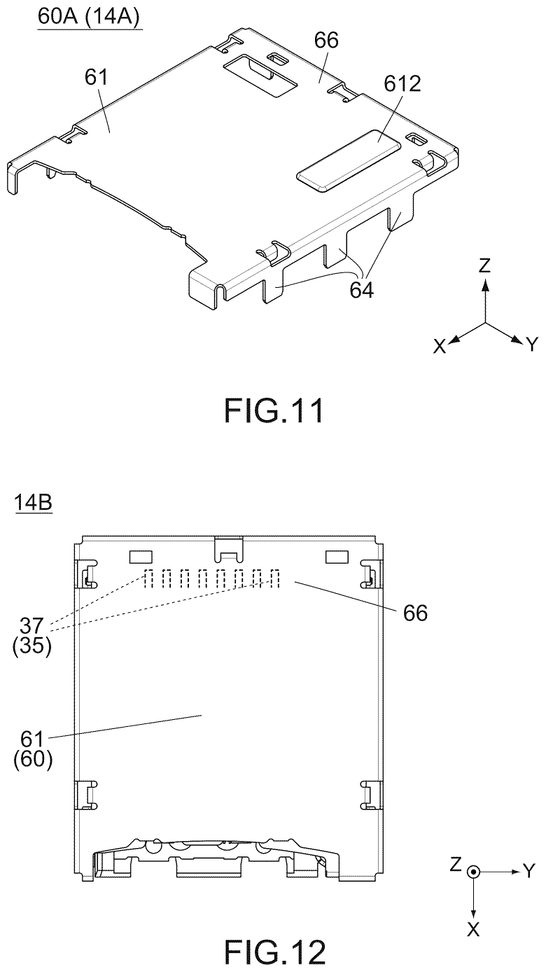

Referring to FIG. 11, the protruding portion 612 protrudes upward from the cover 61. The protruding portion 612 is formed with an upward protruding space (not shown) located therein. Referring to FIG. 10, according to this configuration, the end of the spring piece 412 is movable in a necessary movement distance without providing the thermal conduction sheet 50. Thus, according to the present modification, the bracket 60A can be directly connected to the shell 38 via welding without providing the thermal conduction sheet 50.

Referring to FIGS. 3 and 9, the shield 46 of the shell 38 of the present embodiment covers the surface mount portions 37 of the signal terminals 35 from above and from behind. According to this arrangement, various types of electromagnetic noise such as electromagnetic noise radiated from the surface mount portions 37 can be effectively shielded. Moreover, the electromagnetic noise can be effectively reduced by the connection portions 48 which are grounded to the conductive pads 28 of the board 12. Moreover, the connector device 14 can be formed with an additional thermal conduction path TPA which extends through the connection portions 48. Each of the shield 46 and the connection portions 48 of the present embodiment has the aforementioned configuration. However, the present invention is not limited thereto. For example, the shield 46 may cover the surface mount portions 37 only from above. Thus, in any instance, the shield 46 may cover the surface mount portions 37 of the signal terminals 35. Moreover, as previously described, the shield 46 and the connection portions 48 may be provided as necessary.

Referring to FIGS. 3 and 5, the shield 66 of the bracket 60 of the present embodiment covers the shield 46 and the connection portions 48 of the shell 38 from above and from behind and covers the surface mount portions 37 of the signal terminals 35 from above and from behind. According to this arrangement, the electromagnetic noise radiated from the surface mount portions 37 can be further effectively shielded. Moreover, the electromagnetic noise can be further effectively reduced by the connection portions 68 which are grounded to the through holes 26 of the board 12. However, the present invention is not limited thereto. For example, the shield 66 may cover the surface mount portions 37 only from above. Thus, in any instance, the shield 66 may cover the surface mount portions 37 of the signal terminals 35. In an instance in which the electromagnetic noise can be sufficiently shielded and reduced by the shield 46 and the connection portions 48 of the shell 38, the shield 66 and the connection portions 68 of the bracket 60 do not need to be provided.

The present embodiment can be further variously modified in addition to the already described various modifications. Hereafter, explanation will be made about two modifications.

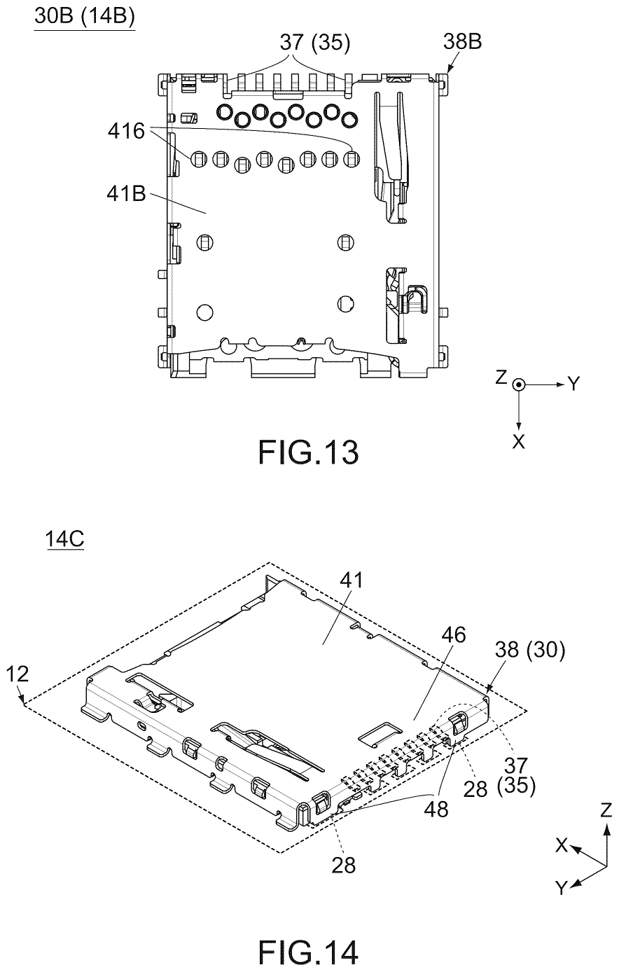

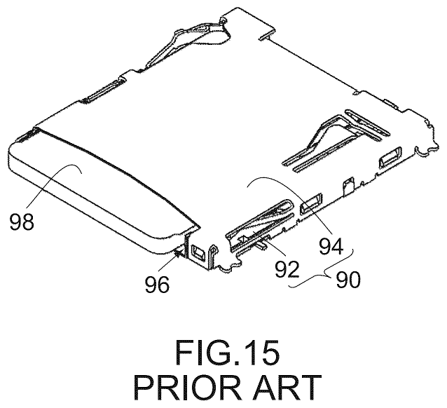

Comparing FIGS. 12 and 13 with FIGS. 8 and 9, a connector device 14B according to a second modification comprises a card connector 30B different from the card connector 30 of the connector device 14. The connector device 14B has a configuration similar to that of the connector device 14 except for this difference. The card connector 30B comprises a shell 38B different from the shell 38 of the card connector 30. The card connector 30B has a configuration similar to that of the card connector 30 except for this difference.

The shell 38B has an upper plate 41B different from the upper plate 41 of the shell 38 and does not have the shield 46 and the connection portions 48 which are provided on the shell 38. The surface mount portions 37 of the signal terminals 35 of the card connector 30B are exposed outward from the shell 38B. However, the shield 66 of the bracket 60 of the present modification covers the surface mount portions 37 of the signal terminals 35. Accordingly, the electromagnetic noise radiated from the surface mount portions 37 can be effectively shielded. Moreover, the electromagnetic noise can be effectively reduced by the connection portions 68 which are grounded to the through holes 26 of the board 12.

Comparing FIG. 14 with FIG. 3, a connector device 14C according to a third modification comprises the card connector 30 same as that of the connector device 14 but does not comprise the thermal conduction sheet 50 and the bracket 60 of the connector device 14. Thus, the connector device 14C comprises only the card connector 30.

Referring to FIG. 14, the shield 46 of the shell 38 of the present modification covers the surface mount portions 37 of the signal terminals 35. According to this arrangement, the electromagnetic noise radiated from the surface mount portions 37 can be effectively shielded. Moreover, the electromagnetic noise can be effectively reduced by the connection portions 48 which are grounded to the conductive pads 28 of the board 12. Moreover, the connector device 14C can be formed with the additional thermal conduction path TPA which extends through the connection portions 48.

Referring to FIG. 14 together with FIG. 2, the connector device 14C is connectable with the heat sink 18 via the thermal conduction sheet 17. More specifically, the thermal conduction sheet 17 can be easily adhered to the middle part of the upper plate 41 of the shell 38 which is flat and has no depressions, no projections and no holes. Thus, the connector device 14C comprises the shell 38, which has the shield 46 and the connection portions 48, instead of the bracket 60 which has the terminals 64 and the cover 61. The present modification provides the connector device 14C suitable for the new heat dissipation structure 10 which is configured to reduce temperature rise of the card 80 accommodated in the card connector 30.

While there has been described what is believed to be the preferred embodiment of the invention, those skilled in the art will recognize that other and further modifications may be made thereto without departing from the spirit of the invention, and it is intended to claim all such embodiments that fall within the true scope of the invention.

What is claimed is

1. A heat dissipation structure configured to reduce temperature rise of a card, wherein:
the heat dissipation structure comprises a board, a connector device and a heat dissipation member;
the board is formed with a through hole;
the connector device comprises a card connector and a bracket made of metal;
the card connector is configured to accommodate the card and is mounted on the board in an up-down direction;
the card connector comprises a shell;
the shell has an upper plate;
the bracket has a terminal and a cover;
the terminal is soldered in the through hole of the board;
the cover of the bracket is connected to the upper plate of the shell; and
the heat dissipation member is connected to the cover.

2. A connector device configured to reduce temperature rise of a card, wherein:
the connector device comprises a card connector and a bracket made of metal;
the card connector is configured to be mounted on a board in an up-down direction and is configured to accommodate the card;
the card connector comprises a shell;
the shell has an upper plate;
the bracket has a terminal and a cover;
the terminal is configured to be soldered in a through hole formed in the board; and
the cover of the bracket is connected to the upper plate of the shell.

3. The connector device as recited in claim 2, wherein:
the upper plate of the shell is formed with a passing hole;
the passing hole is located at a part of the upper plate other than a periphery of the upper plate in a horizontal plane perpendicular to the up-down direction and passes through the upper plate in the up-down direction;
the cover of the bracket covers the passing hole; and
the passing hole is invisible when the connector device is seen from above.

4. The connector device as recited in claim 2, wherein:
the card connector comprises a signal terminal;
the signal terminal has a surface mount portion;
the bracket has a shield and a connection portion;
the shield covers the surface mount portion;
the connection portion is configured to be soldered in a through hole formed in the board; and
the connection portion extends downward from the shield.

5. The connector device as recited in claim 2, wherein:
the card connector comprises a signal terminal;
the signal terminal has a surface mount portion;
the shell has a shield and a connection portion;
the shield covers the surface mount portion;
the connection portion is configured to be connected to the board;
the connection portion extends downward from the shield; and
the connector device comprises the shell, which has the shield and the connection portion, instead of the bracket which has the terminal and the cover.

6. The connector device as recited in claim 2, wherein:
the card connector comprises a signal terminal;
the signal terminal has a surface mount portion;
the shell has a shield and a connection portion;
the shield covers the surface mount portion;
the connection portion is configured to be connected to the board; and
the connection portion extends downward from the shield.

7. The connector device as recited in claim 3, wherein:
the card connector comprises a signal terminal;
the signal terminal has a surface mount portion;
the bracket has a shield and a connection portion;
the shield covers the surface mount portion;
the connection portion is configured to be soldered in a through hole formed in the board; and
the connection portion extends downward from the shield.

8. The connector device as recited in claim 3, wherein:
the card connector comprises a signal terminal;
the signal terminal has a surface mount portion;
the shell has a shield and a connection portion;
the shield covers the surface mount portion;
the connection portion is configured to be connected to the board;
the connection portion extends downward from the shield; and
the connector device comprises the shell, which has the shield and the connection portion, instead of the bracket which has the terminal and the cover.

9. The connector device as recited in claim 3, wherein:
the card connector comprises a signal terminal;
the signal terminal has a surface mount portion;
the shell has a shield and a connection portion;
the shield covers the surface mount portion;
the connection portion is configured to be connected to the board; and
the connection portion extends downward from the shield.
